(19) United States
(12) Patent Application Publication
(10) Pub. No.: US 2012/0171625 A1
(43) Pub. Date: Jul. 5, 2012

(54) IMMERSION EXPOSURE APPARATUS AND METHOD OF OPERATING THEREOF

(76) Inventor: Tah-Te Shih, Taipei (TW)

(21) Appl. No.: 13/071,489

(22) Filed: Mar. 24, 2011

(30) Foreign Application Priority Data
Jan. 3, 2011 (TW) 100100047

(51) Int. Cl. G03F 7/20; G03B 27/52

(52) U.S. Cl. 430/322; 355/30

(57) ABSTRACT

An immersion exposure apparatus includes a light source, a projection lens set, a photomask, a liquid medium, and a supporting stage. The projection lens set has a front surface facing the light source and a first back surface facing away from the light source. The photomask has a second back surface facing away from the light source. The photomask is disposed between the light source and the projection lens set. The liquid medium is disposed the front surface and the second back surface. The liquid medium contacts the front surface and the second back surface. The supporting stage is disposed at a side of the first back surface of the projection lens set. A substrate is disposed on the supporting stage. The liquid medium may be water or other liquid.

### BACKGROUND OF THE INVENTION

1. Field of the Invention

The present invention relates to an immersion exposure apparatus and a method of operating thereof, and more particularly, to an immersion exposure apparatus with a liquid medium, which is employed to greatly enhance a resolution limitation of the exposure apparatus, and a method of operating thereof.

2. Description of the Prior Art

Photolithographic technology plays an important role in integrated circuit manufacturing. As demands for higher performance of the integrated circuit products keep increasing, the photolithographic technologies with higher resolution are steadily developed for manufacturing circuits with smaller line width. As the integrated density of the integrated circuit increases, devices with smaller dimension are required in the integrated circuit. Therefore, related industries endeavor to enhance the resolution limit of the optical exposure tool.

The conventional methods for enhancing the resolution of the exposure tool include: reducing wavelength of light source; utilizing resolution enhancement techniques, such as phase shift masks or off-axis illuminations; and modifying optical systems to increase the numerical aperture (N.A.). However, the conventional methods have never accomplished satisfying performances.

Therefore, in related industries, a novel exposure apparatus, which is compatible with the current process and capable of greatly enhancing the resolution limit, is eagerly demanded.

### SUMMARY OF THE INVENTION

The present invention provides an immersion exposure apparatus. The immersion exposure apparatus includes a light source, a projection lens set, a photomask, a liquid medium, and a supporting stage. The projection lens set has a front surface facing the light source and a first back surface facing away from the light source. The photomask has a second back surface facing away from the light source. The photomask is disposed between the light source and the projection lens set. The liquid medium is disposed between the front surface of the projection lens set and the second back surface of the photomask. The liquid medium contacts the front surface and the second back surface. The supporting stage is disposed at a same side of the first back surface of the projection lens set, and a substrate is disposed on the supporting stage.

The present invention provides a method of operating an immersion exposure apparatus. The method of operating the immersion exposure apparatus includes the following steps. Firstly, an immersion exposure apparatus and a substrate are provided. The substrate is covered with a photoresist. The immersion exposure apparatus includes a light source, a projection lens set, a photomask, a liquid medium, and a supporting stage. The projection lens set has a front surface facing the light source and a first back surface facing away from the light source. The photomask has a second back surface facing away from the light source, and the photomask is disposed between the light source and the projection lens set. The photomask has a pattern. The liquid medium is disposed between the front surface of the projection lens set and the second back surface of the photomask. The liquid medium contacts the front surface and the second back surface. The supporting stage is disposed at a same side of the first back surface of the projection lens set. The substrate is disposed on the supporting stage. The light source passes through the photomask, the liquid medium and the projection lens set for defining the pattern on the photoresist, wherein the light source is refracted by the liquid medium before reaching the projection lens set. The light source is diffracted after passing through the photomask to generate a zero order beam and a first order beam. The zero order beam and the first order beam penetrate through the projection lens set after being refracted by the liquid medium.

In the immersion exposure apparatus of the present invention, the liquid medium disposed between the projection lens set and the photomask is employed to enhance the resolution limit, and a diameter of the projection lens set may be effectively reduced.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram illustrating the immersion exposure apparatus according to the preferred embodiment of the present invention.

FIG. 2 is a partially enlarged diagram of FIG. 1.

### DETAILED DESCRIPTION

To provide a better understanding of the present invention to skilled users in the technology of the present invention, preferred embodiments will be detailed as follows. The preferred embodiments of the present invention are illustrated in the accompanying drawings with numbered elements to elaborate the contents and effects to be achieved.

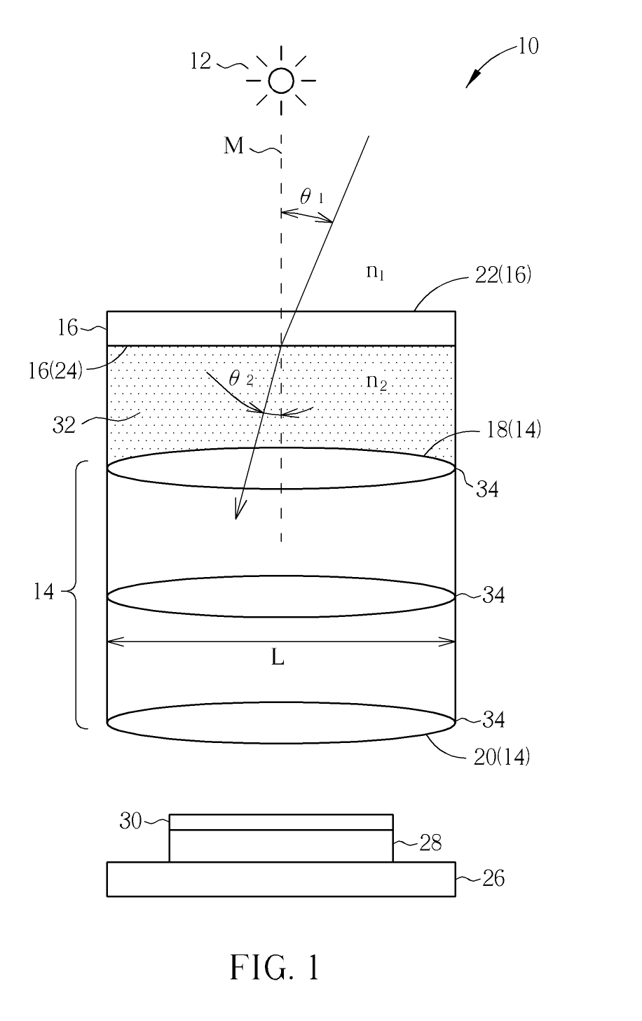

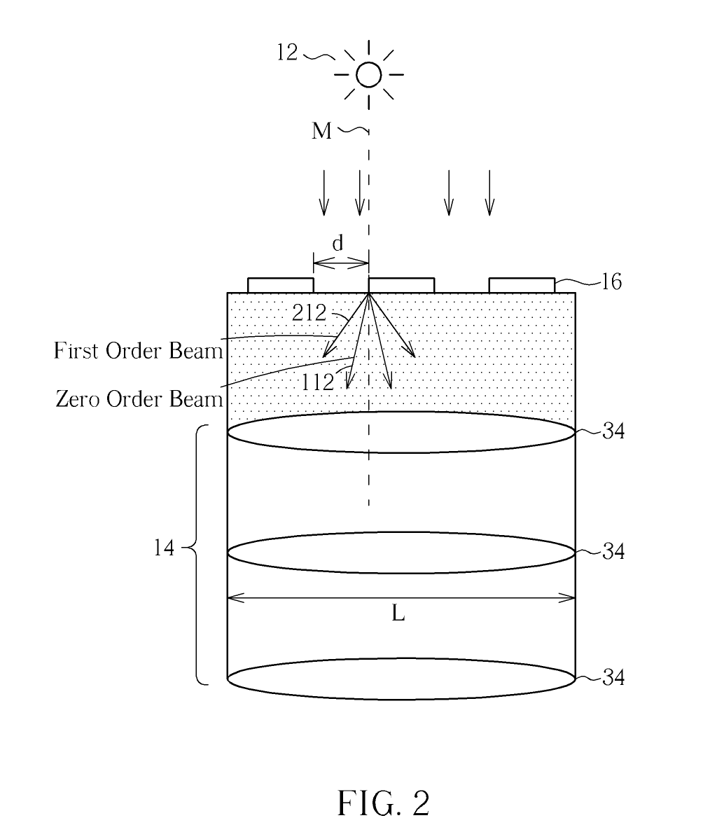

Please refer to FIG. 1 and FIG. 2. FIG. 1 is a schematic diagram illustrating the immersion exposure apparatus according to the preferred embodiment of the present invention. FIG. 2 is a partially enlarged diagram of FIG. 1. As shown in FIG. 1, an immersion exposure apparatus 10 includes a light source 12, a projection lens set 14, a photomask 16, a liquid medium 32, and a supporting stage 26. The photomask 16 is disposed between the light source 12 and the projection lens set 14. The projection lens set 14 has a front surface 18 facing the light source 12 and a first back surface 20 facing away from the light source 12. The photomask 16 has a front surface 22 facing the light source 12 and a second back surface 24 facing away from the light source 12. The photomask 16 has designed patterns of integrated circuits. The supporting stage 26 is disposed at a same side of the first back surface 20 of the projection lens set 14. A substrate 28 is disposed on the supporting stage 26. The substrate 28 is covered with a photoresist 30. It is worth noticing that the liquid medium 32 is disposed between the front surface 18 of the projection lens set 14 and the second back surface 24 of the photomask 16, and the liquid medium 32 contacts the front surface 18 and the second back surface 24. According to the preferred embodiment of the present invention, the liquid medium 32 may be water, but the present invention is not limit to this and any of the other high reflective mediums with refractive indexes larger than 1 may be employed in the present invention.

A gaseous medium such as air may exist between the first back surface 20 of the projection lens set 14 and the photoresist 30 on the substrate 28, but the present invention is not limited to this. Conventional immersion photolithography may also be employed in the present invention. For example, liquid mediums may be disposed between the front surface 18 of the projection lens set 14 and the second back surface 24 of the photomask 16, and the liquid mediums may also be disposed between the first back surface 20 of the projection lens set 14 and the photoresist 30 on the substrate 28.

The projection lens set 14 includes at least a projection lens 34. The projection lens set 14 usually consists of a plurality of projection lenses 34 for successfully making the light source 12 focused on the photoresist 30.

The immersion exposure apparatus illustrated in FIG. 1 may be used for the exposure process in the semiconductor manufacturing process. The method of operating the immersion exposure apparatus includes the following steps.

Firstly, the light source 12 of the immersion exposure apparatus 10 is switched on, and the light source 12 may orderly pass through the photo mask 16, the liquid medium 32 and the projection lens set 14, and the light source 12 may be focused on the photoresist 30 for defining the pattern of the photomask 16 on the photoresist 30. It is worthy of note that the light source 12 is refracted by the liquid medium 32 before reaching the projection lens set 14. Additionally, as shown in FIG. 2, the pattern of integrated circuits on the photomask 16 has extremely small spacing d allowing the light source 12 to pass through. However, the light source 12 may be divided into beams with different orders, such as a zero order beam 112 and a first order beam 212, by diffraction effects after passing through the extremely small spacing d. In the exposure process, the photoresist 30 on the substrate 28 has to be irradiated by either the zero order beam 112 or the first order beam 212 for successful exposure. According to the immersion exposure apparatus 10 in the present invention, sufficient zero order beams 112 or sufficient first order beams 212 may be gathered to irradiate the photoresist 30 on the substrate 28.

The light source 12 is diffracted after passing through the photomask 16. Before reaching the projection lens set 14, the diffracted light source 12 such as the zero order beam 112 and the first order beam 212 may be refracted by the liquid medium 32. The well-known Snell's law may be presented by equation (1) listed below. The equation (1) describes that the incident light travels from one media with an index of refraction of n₁ into another media with an index of refraction of n₂. θ₁ represents an included angle between the incident light and a normal line of an interface, and θ₂ represents an included angle between a refracted light and the normal line of the interface.

n₁ Sin θ₁=n₂ Sin θ2 (1)

Please refer to FIG. 1 again. A medium which contacts the front surface 22 of the photomask 16 is air, hence n₁ equals to 1. A medium which contacts the second back surface 24 of the photomask 16 is water, hence n₂ substantially equals 1.33. Therefore, according to the above-mentioned Snell's law, θ₁ may be substantially larger than θ₂. Please refer to both FIG. 1 and FIG. 2. The light source 12 is diffracted to generate the zero order beam 112 or the first order beam 212. The zero order beam 112 or the first order beam 212 may get close to a normal line M after passing the liquid medium 32. Under this condition, even if a long axis L of the projection lens 34 is reduced, sufficient light source 12 could still be gathered to penetrate the projection lenses 34. Therefore, a volume of the projection lens set 14 of the immersion exposure apparatus 10 may be further reduced for lowering a manufacturing cost of the projection lens set 14.

As known by a person skilled in the art and a person of ordinary knowledge, a resolution (r₀) of the immersion exposure apparatus 10 may be presented by equation (2) listed below. In equation (2), λ represents a wavelength of the light source 12, and NA represents a numerical aperture. The numerical aperture may also be presented by equation (3) listed below. In equation (3), n_{eff} represents an effective index of refraction of mediums between the substrate 28 and the light source 12, and θ represents a half of an aperture angle of the projection lens 34. According to both equation (2) and equation (3), higher resolution may be induced when n_{eff} becomes larger.

$$\begin{matrix}{r}_{0} = \frac{λ}{NA} & ( 2 ) \\ NA = {n}_{eff} sin θ & ( 3 )\end{matrix}$$

In the conventional exposure apparatus, the medium between the front surface of the projection lens set and the back surface of the photomask is air. Therefore, the effective index of refraction n_{eff} may be increased and θ may become smaller because of the liquid medium 32 disposed between the front surface 18 of the projection lens set 14 and the second back surface 24 of the photomask 16 in the present invention. Consequently, the resolution of the immersion exposure apparatus 10 may be enhanced because the diffraction orders of beams, which could be received by the projection lens 34, increase.

To summarize all the descriptions above, the liquid medium such as water disposed between the photomask and the projection lens set is the main feature of the immersion exposure apparatus in the present invention. Compared to the conventional exposure apparatus, the resolution of the immersion exposure apparatus in the present invention is enhanced because the effective index of refraction is increased by the liquid medium. In addition, the volume of the projection lens may be further reduced without influencing the light-gathering ability of the projection lens, because the light source passing through the photomask may get close to the normal line of the projection lens, i.e. the center of the projection lens after being refracted by the liquid medium. In respect of the complexity and the cost of manufacturing the projection lens set, the manufacturing cost of the projection lens with smaller volume is lower than the manufacturing cost of the projection lens with larger volume, and the manufacturing complexity is much lower for the projection lens with smaller volume. Consequently, according to the immersion exposure apparatus in the present invention, the resolution may be effectively enhanced, the volume of the projection lens set may be reduced, and the purposes of space-saving and manufacturing cost reduction may be then achieved.

Those skilled in the art will readily observe that numerous modifications and alterations of the device and method may be made while retaining the teachings of the invention.

What is claimed is:

1. An immersion exposure apparatus, comprising:
a light source;
a projection lens set, having a front surface facing the light source and a first back surface facing away from the light source;
a photomask, having a second back surface facing away from the light source, wherein the photomask is disposed between the light source and the projection lens set;
a liquid medium disposed between the front surface of the projection lens set and the second back surface of the photomask, the liquid medium contacting the front surface and the second back surface; and
a supporting stage disposed at a side of the first back surface of the projection lens set, wherein a substrate is disposed on the supporting stage.

2. The immersion exposure apparatus of claim 1, further comprising a gaseous medium disposed between the first back surface and the substrate.

3. The immersion exposure apparatus of claim 1, wherein the gaseous medium includes air.

4. The immersion exposure apparatus of claim 1, wherein the liquid medium includes water.

5. The immersion exposure apparatus of claim 1, wherein the projection lens set includes at least one projection lens.

6. A method of operating an immersion exposure apparatus, comprising:
providing an immersion exposure apparatus and a substrate covered with a photoresist, wherein the immersion exposure apparatus includes:
a light source;
a projection lens set, having a front surface facing the light source and a first back surface facing away from the light source;
a photomask, having a second back surface facing away from the light source, wherein the photomask is disposed between the light source and the projection lens set, and the photomask has a pattern;
a liquid medium disposed between the front surface of the projection lens set and the second back surface of the photomask, the liquid medium contacting the front surface and the second back surface; and
a supporting stage disposed at a side of the first back surface of the projection lens set, wherein the substrate is disposed on the supporting stage; and
making the light source pass through the photomask, the liquid medium and the projection lens set for defining the pattern on the photoresist, wherein the light source is refracted by the liquid medium before reaching the projection lens set.

7. The method of operating the immersion exposure apparatus in claim 6, wherein the immersion exposure apparatus further comprises a gaseous medium disposed between the projection lens set and the substrate.

8. The method of operating the immersion exposure apparatus in claim 7, wherein the gaseous medium includes air.

9. The method of operating the immersion exposure apparatus in claim 6, wherein the liquid medium includes water.

10. The method of operating the immersion exposure apparatus in claim 6, wherein the light source is diffracted after passing through the photomask to generate a zero order beam, and the zero order beam penetrates through the projection lens set after being refracted by the liquid medium.

11. The method of operating the immersion exposure apparatus in claim 6, wherein the light source is diffracted after passing through the photomask to generate a first order beam, and the first order beam penetrates through the projection lens set after being refracted by the liquid medium.

12. The method of operating the immersion exposure apparatus in claim 6, wherein the projection lens set includes at least one projection lens.
